(19) United States
(12) Patent Application Publication
(10) Pub. No.: US 2026/0171997 A1
(43) Pub. Date: Jun. 18, 2026

(54) IMPEDANCE MATCHING CIRCUIT AND TRANSMITTER

(71) Applicant: PACIFIC INDUSTRIAL CO., LTD., Gifu-ken (JP)

(72) Inventor: Makoto Kuno, Ogaki-shi, Gifu-ken (JP)

(21) Appl. No.: 18/845,959

(22) PCT Filed: Mar. 3, 2023
(86) PCT No.: PCT/JP2023/008027

§ 371 Date: Sep. 11, 2024

(51) Int. Cl. H03H 7/38; H01Q 1/22; H01Q 5/50; H04B 1/04

(52) U.S. Cl. CPC H03H 7/38; H01Q 1/2241; H01Q 5/50; H04B 1/0458; H03H 2007/386

(57) ABSTRACT

A matching circuit (31) includes a first parallel resonance circuit (32), a second parallel resonance circuit (36), a first matching unit (35), and a second matching unit (39). The resonance frequency of the first parallel resonance circuit (32) is a first frequency. The resonance frequency of the second parallel resonance circuit (36) is a second frequency. The first matching unit (35) is connected in series with the first parallel resonance circuit (32). The second matching unit (39) is connected in series with the second parallel resonance circuit (36). The first parallel resonance circuit (32) and the second parallel resonance circuit (36) are connected in parallel with each other and connected in series with the transmission antenna (27).

### TECHNICAL FIELD

The present disclosure relates to a matching circuit and a transmitter.

### BACKGROUND ART

Antennas are used for communication using wireless signals. An antenna is connected to a matching circuit that performs impedance matching between the antenna and a wireless communication circuit. Such a matching circuit is disclosed, for example, in Patent Literature 1.

### CITATION LIST

### Patent Literature

Patent Literature 1: Japanese Laid-Open Patent Publication No. 2022-8112

### SUMMARY OF INVENTION

### Technical Problem

In a case in which communication is performed using wireless signals of multiple frequencies, matching circuits need to be provided to correspond to the respective frequencies. This configuration can significantly complicate a communication circuit that uses wireless signals of multiple frequencies, due to mutual influences of the matching circuits.

### Solution to Problem

In accordance with a first aspect of the present disclosure, a matching circuit connected to an antenna includes a first parallel resonance circuit, a second parallel resonance circuit, a first matching unit, and a second matching unit. The first parallel resonance circuit includes a first coil and a first capacitor that are connected in parallel with each other. The first parallel resonance circuit has a resonance frequency that is a first frequency. The second parallel resonance circuit includes a second coil and a second capacitor that are connected in parallel with each other. The second parallel resonance circuit has a resonance frequency that is a second frequency. The first matching unit is configured to perform impedance matching between the antenna and a wireless communication circuit at the second frequency. The first matching unit is connected in series with the first parallel resonance circuit. The second matching unit is configured to perform impedance matching between the antenna and the wireless communication circuit at the first frequency. The second matching unit is connected in series with the second parallel resonance circuit. The first parallel resonance circuit and the second parallel resonance circuit are connected in parallel with each other and connected in series with the antenna.

When the wireless communication circuit performs communication using a wireless signal of the first frequency, the impedance of the first parallel resonance circuit is effectively infinite. When the wireless communication circuit performs communication using a wireless signal of the first frequency, the second matching unit performs impedance matching between the antenna and the wireless communication circuit. At this time, since the first matching unit, which is connected in series with the first parallel resonance circuit, is, in effect, not connected to the antenna, the first matching unit is prevented from affecting the second matching unit. Likewise, when the wireless communication circuit performs communication using a wireless signal of the second frequency, the second matching unit, which is connected in series with the second parallel resonance circuit, is, in effect, not connected to the antenna. This prevents the second matching unit from affecting the first matching unit. Since the first matching unit and the second matching unit are prevented from affecting each other, impedance matching can be performed regardless of whether the frequency of the wireless signal is the first frequency or the second frequency. The use of the parallel resonance circuits allows impedance matching to be performed with a simple configuration regardless of whether the frequency of the wireless signal is the first frequency or the second frequency.

In accordance with a second aspect of the present disclosure, a transmitter attached to a wheel of a vehicle includes a transmission antenna, a transmission circuit, and a matching circuit that performs impedance matching between the transmission antenna and the transmission circuit. The matching circuit includes a first parallel resonance circuit, a second parallel resonance circuit, a first matching unit, and a second matching unit. The first parallel resonance circuit includes a first coil and a first capacitor that are connected in parallel with each other. The first parallel resonance circuit has a resonance frequency that is a first frequency. The second parallel resonance circuit includes a second coil and a second capacitor that are connected in parallel with each other. The second parallel resonance circuit has a resonance frequency that is a second frequency. The first matching unit is configured to perform impedance matching between the transmission antenna and the transmission circuit at the second frequency. The first matching unit is connected in series with the first parallel resonance circuit. The second matching unit is configured to perform impedance matching between the transmission antenna and the transmission circuit at the first frequency. The second matching unit is connected in series with the second parallel resonance circuit. The first parallel resonance circuit and the second parallel resonance circuit are connected in parallel with each other and connected in series with the transmission antenna.

Since the first matching unit and the second matching unit are prevented from affecting each other, impedance matching can be performed regardless of whether the frequency of the wireless signal is the first frequency or the second frequency.

In the above-described transmitter, the matching circuit may be placed upstream of the transmission antenna.

In the above-described transmitter, the matching circuit may be placed between the transmission circuit and the transmission antenna.

### BRIEF DESCRIPTION OF DRAWINGS

FIG. 1 is a schematic diagram showing an example of a tire condition monitoring system.

FIG. 2 is a schematic diagram showing a transmitter of the tire condition monitoring system shown in FIG. 1.

FIG. 3 is a schematic diagram showing a matching circuit in the transmitter shown in FIG. 2.

FIG. 4 is a schematic diagram showing a matching circuit according to a modification.

### DESCRIPTION OF EMBODIMENTS

A matching circuit and a transmitter according to one embodiment will now be described.

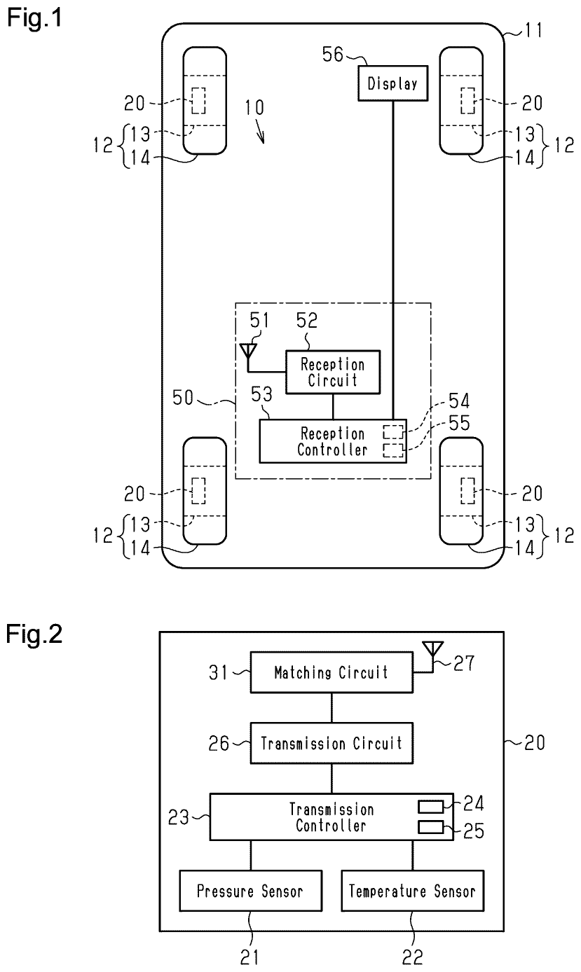

As shown in FIG. 1, a vehicle 11 includes four wheel assemblies 12. Each wheel assembly 12 includes a wheel 13 and a tire 14, which is attached to the wheel 13.

The vehicle 11 includes a tire condition monitoring system 10. The tire condition monitoring system 10 includes at least one transmitter 20. In the present embodiment, each wheel assembly 12 is provided with a transmitter 20. The transmitter 20 is attached to the wheel 13. For example, the transmitter 20 is attached to the wheel 13 by being attached to a tire valve attached to the wheel 13.

### Transmitter

As shown in FIG. 2, each transmitter 20 includes a pressure sensor 21. The pressure sensor 21 detects the air pressure of the corresponding tire 14. The transmitter 20 includes a temperature sensor 22. The temperature sensor 22 detects the internal temperature of the corresponding tire 14.

The transmitter 20 includes a transmission controller 23. The transmission controller 23 includes a processor 24 and a storage unit 25. The processor 24 is, for example, a central processing unit (CPU), a graphics processing unit (GPU), or a digital signal processor (DSP). The storage unit 25 includes a random access memory (RAM) and a read-only memory (ROM). The storage unit 25 stores program codes or instructions configured to cause the processor 24 to execute processes. The storage unit 25, or a computer-readable medium, includes any type of medium that is accessible by general-purpose computers or dedicated computers. The transmission controller 23 may include a hardware circuit such as an application-specific integrated circuit (ASIC) or a field-programmable gate array (FPGA). The transmission controller 23, which is processing circuitry, may include one or more processors that run according to a computer program, one or more hardware circuits (e.g., ASIC or FPGA), or a combination thereof.

The transmitter 20 includes a transmission circuit 26. The transmission circuit 26 modulates transmission data received from the transmission controller 23. The transmission data includes data formatted according to a protocol. The transmission data includes pressure data, temperature data, and identification information. The pressure data is a detection result of the pressure sensor 21. The temperature data is a detection result of the temperature sensor 22. The identification information is used to identify each of the transmitters 20. The identification information is, for example, an ID code set for each transmitter 20.

The transmitter 20 includes a transmission antenna 27. The transmission antenna 27 transmits the transmission data modulated by the transmission circuit 26 as a wireless signal. The transmitter 20 is configured to transmit wireless signals of different frequencies. The frequencies of wireless signals differ depending on the regulations of each country. Thus, the transmitter 20 is configured to transmit wireless signals having a frequency corresponding to the country in which the transmitter 20 is used. In the present embodiment, the transmitter 20 is configured to switch between transmitting a wireless signal in the 315 MHz band and transmitting a wireless signal the 434 MHz band. The 315 MHz band is an example of a first frequency. The 434 MHz band is an example of a second frequency.

### Matching Circuit

The transmitter 20 includes a matching circuit 31. The matching circuit 31 is connected to the transmission antenna 27. The matching circuit 31 is placed upstream of the transmission antenna 27. In other words, the matching circuit 31 is placed between the transmission circuit 26 and the transmission antenna 27. The matching circuit 31 performs impedance matching between the transmission antenna 27 and the transmission circuit 26. The transmission antenna 27 is an example of an antenna. The transmission circuit 26 is an example of a wireless communication circuit.

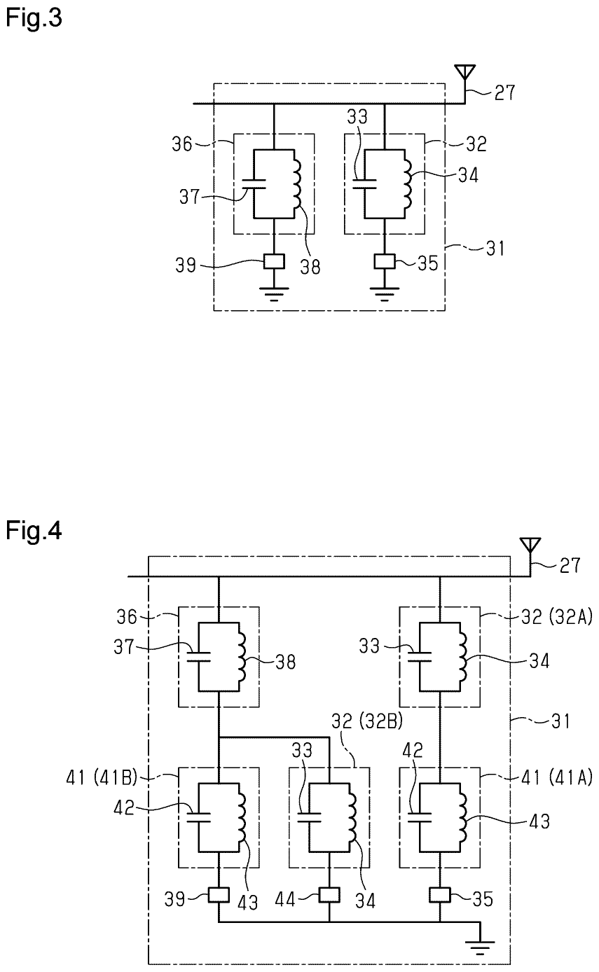

As shown in FIG. 3, the matching circuit 31 includes a first parallel resonance circuit 32. The first parallel resonance circuit 32 includes a first capacitor 33 and a first coil 34. The first coil 34 and the first capacitor 33 are connected in parallel with each other. The inductance of the first coil 34 and the capacitance of the first capacitor 33 are set such that resonance occurs at the first frequency. The resonance frequency of the first parallel resonance circuit 32 is the first frequency.

The matching circuit 31 includes a second parallel resonance circuit 36. The second parallel resonance circuit 36 includes a second capacitor 37 and a second coil 38. The second coil 38 and the second capacitor 37 are connected in parallel with each other. The inductance of the second coil 38 and the capacitance of the second capacitor 37 are set such that resonance occurs at the second frequency. The resonance frequency of the second parallel resonance circuit 36 is the second frequency.

The first parallel resonance circuit 32 and the second parallel resonance circuit 36 are connected in parallel with each other and connected in series with the transmission antenna 27.

The matching circuit 31 includes a first matching unit 35. The first matching unit 35 performs impedance matching between the transmission antenna 27 and the transmission circuit 26 at the second frequency. Specifically, the first matching unit 35 performs impedance matching between the transmission antenna 27 and the transmission circuit 26 when the transmitter 20 transmits a wireless signal of the second frequency. The first matching unit 35 includes, for example, a coil and a capacitor. The first matching unit 35 is connected in series with the first parallel resonance circuit 32.

The matching circuit 31 includes a second matching unit 39. The second matching unit 39 performs impedance matching between the transmission antenna 27 and the transmission circuit 26 at the first frequency. Specifically, the second matching unit 39 performs impedance matching between the transmission antenna 27 and the transmission circuit 26 when the transmitter 20 transmits a wireless signal of the first frequency. The second matching unit 39 includes, for example, a coil and a capacitor. The second matching unit 39 is connected in series with the second parallel resonance circuit 36.

### Receiver

As shown in FIG. 1, the tire condition monitoring system 10 includes a receiver 50. The receiver 50 includes a reception antenna 51. The reception antenna 51 receives wireless signals transmitted from the transmitters 20.

The receiver 50 includes a reception circuit 52. The reception circuit 52 demodulates the wireless signal received by the reception antenna 51. The reception circuit 52 thus obtains transmission data.

The receiver 50 includes a reception controller 53. The hardware configuration of the reception controller 53 is, for example, the same as that of the transmission controller 23. The reception controller 53 includes, for example, a processor 54 and a storage unit 55. The reception controller 53 receives the transmission data from the reception circuit 52. The reception controller 53 thus obtains the pressure data, the temperature data, and the identification information of the transmitter 20 that has transmitted the wireless signal. In this manner, the transmitter 20 and the receiver 50 communicate with each other using wireless signals. The communication includes transmission of wireless signals and reception of the wireless signals.

The vehicle 11 includes a display 56. The display 56 is, for example, controlled by the reception controller 53. The reception controller 53 determines whether there is an anomaly in any of the tires 14 based on, for example, pressure data and temperature data.

When there is an anomaly in any of the tires 14, the reception controller 53 may display this information on the display 56.

### Operation of Present Embodiment

When the transmission circuit 26 transmits a wireless signal of the first frequency, the impedance of the first parallel resonance circuit 32 is effectively infinite. When the transmission circuit 26 transmits a wireless signal of the first frequency, the second matching unit 39 performs impedance matching between the transmission antenna 27 and the transmission circuit 26. At this time, the first matching unit 35, which is connected in series with the first parallel resonance circuit 32, is, in effect, not connected to the transmission antenna 27.

When the transmission circuit 26 transmits a wireless signal of the second frequency, the impedance of the second parallel resonance circuit 36 is effectively infinite. When the transmission circuit 26 transmits a wireless signal of the second frequency, the first matching unit 35 performs impedance matching between the transmission antenna 27 and the transmission circuit 26. At this time, the second matching unit 39, which is connected in series with the second parallel resonance circuit 36, is effectively not connected to the transmission antenna 27.

### Advantages of Present Embodiment

(1) When the transmission circuit 26 transmits a wireless signal of the first frequency, the first matching unit 35 is effectively not connected to the transmission antenna 27 via the first parallel resonance circuit 32. When the transmission circuit 26 transmits a wireless signal of the first frequency, the first matching unit 35 is prevented from affecting the second matching unit 39. Likewise, when the transmission circuit 26 transmits a wireless signal of the second frequency, the second matching unit 39 is prevented from affecting the first matching unit 35. Since the first matching unit 35 and the second matching unit 39 are prevented from affecting each other, impedance matching can be performed regardless of whether the frequency of the wireless signal is the first frequency or the second frequency. The use of the parallel resonance circuits 32, 36 allows impedance matching to be performed with a simple configuration regardless of whether the frequency of the wireless signal is the first frequency or the second frequency.
(2) The transmitter 20 is attached to the wheel 13 of the vehicle 11. In a case in which a single transmitter transmits a wireless signal of the first frequency and a wireless signal of the second frequency, impedance matching needs to be performed in correspondence with each frequency. This can be achieved by providing individual transmission antennas for each frequency and corresponding matching units for each antenna, allowing a single transmitter to transmit wireless signals of both the first and second frequencies. However, due to the spatial constraints of the transmitter mounted on the wheel 13, it is essential to minimize its size. Providing individual transmission antennas for the respective frequencies may result in an increase in the size of the transmitter. Therefore, it is necessary to use a single transmission antenna to transmit wireless signals of both the first and second frequencies. The use of the matching circuit 31 described in the embodiment prevents the first matching unit 35 and the second matching unit 39 from affecting each other even when the single transmission antenna 27 is used. This allows a single transmitter 20 to transmit a wireless signal of the first frequency and a wireless signal of the second frequency, while limiting an increase in the size of the transmitter 20.
(3) The matching circuit 31 is placed upstream of the transmission antenna 27.

When impedance matching between the transmission antenna 27 and the transmission circuit 26 is performed, the impedance is measured by an impedance analyzer. The matching circuit 31 is adjusted based on the impedance measured by the impedance analyzer. If the matching circuit 31 were placed downstream of the transmission antenna 27, the impedance measured by the impedance analyzer would include elements of the transmission antenna 27, making it difficult to adjust the matching circuit 31. In contrast, by placing the matching circuit 31 upstream of the transmission antenna 27, the matching circuit 31 can be adjusted based on impedance that does not include elements of the transmission antenna 27. This facilitates adjustment of the matching circuit 31.

### Modifications

The above-described embodiment may be modified as follows. The above-described embodiment and the following modifications can be combined as long as the combined modifications remain technically consistent with each other.

The matching circuit 31 may be placed downstream of the transmission antenna 27. The transmitter 20 may transmit wireless signals of three or more frequencies. In this case, the number of matching units needs to be increased in accordance with the number of the frequencies. The parallel resonance circuit simply may be provided such that a matching unit that does not correspond to the frequency of a wireless signal is effectively not connected to the transmission antenna 27. As an example, a matching circuit 31 will be described that transmits wireless signals of three frequencies.

As shown in FIG. 4, the matching circuit 31 includes two first parallel resonance circuits 32 and one second parallel resonance circuit 36. The matching circuit 31 includes two third parallel resonance circuits 41. The third parallel resonance circuits 41 each include a third capacitor 42 and a third coil 43. The third coil 43 and the third capacitor 42 are connected in parallel with each other. The inductance of the third coil 43 and the capacitance of the third capacitor 42 are set such that resonance occurs at a third frequency. The resonance frequency of the third parallel resonance circuit 41 is the third frequency. The third frequency differs from the first frequency and the second frequency.

The matching circuit 31 includes a third matching unit 44. The third matching unit 44 performs impedance matching between the transmission antenna 27 and the transmission circuit 26 at the third frequency. Specifically, the third matching unit 44 performs impedance matching between the transmission antenna 27 and the transmission circuit 26 when the transmitter 20 transmits a wireless signal of the third frequency. The third matching unit 44 includes, for example, a coil and a capacitor.

The two first parallel resonance circuits 32 are respectively referred to as a first parallel resonance circuit 32A and a first parallel resonance circuit 32B. The two third parallel resonance circuits 41 are respectively referred to as a third parallel resonance circuit 41A and a third parallel resonance circuit 41B.

The first parallel resonance circuit 32A and the second parallel resonance circuit 36 are connected in parallel with each other and connected in series with the transmission antenna 27. The third parallel resonance circuit 41A is connected in series with the first parallel resonance circuit 32A. The first matching unit 35 is connected in series with the first parallel resonance circuit 32A via the third parallel resonance circuit 41A.

The first parallel resonance circuit 32B is connected in series with the second parallel resonance circuit 36. The third matching unit 44 is connected in series with the first parallel resonance circuit 32B.

The third parallel resonance circuit 41B is connected in series with the second parallel resonance circuit 36. The second matching unit 39 is connected in series with the second parallel resonance circuit 36 via the third parallel resonance circuit 41B.

When the transmission circuit 26 transmits a wireless signal of the first frequency, the impedance of the first parallel resonance circuit 32A is effectively infinite. Accordingly, the first matching unit 35 is effectively not connected to the transmission antenna 27. When the transmission circuit 26 transmits a wireless signal of the first frequency, the impedance of the first parallel resonance circuit 32B is effectively infinite. Accordingly, the third matching unit 44 is effectively not connected to the transmission antenna 27. Thus, when the transmission circuit 26 transmits a wireless signal of the first frequency, the second matching unit 39 performs impedance matching between the transmission antenna 27 and the transmission circuit 26.

When the transmission circuit 26 transmits a wireless signal of the second frequency, the impedance of the second parallel resonance circuit 36 is effectively infinite.

Accordingly, the second matching unit 39 and the third matching unit 44 is effectively not connected to the transmission antenna 27. Thus, when the transmission circuit 26 transmits a wireless signal of the second frequency, the first matching unit 35 performs impedance matching between the transmission antenna 27 and the transmission circuit 26.

When the transmission circuit 26 transmits a wireless signal of the third frequency, the impedance of the third parallel resonance circuit 41A is effectively infinite. Accordingly, the first matching unit 35 is effectively not connected to the transmission antenna 27. When the transmission circuit 26 transmits a wireless signal of the third frequency, the impedance of the third parallel resonance circuit 41B is effectively infinite. Accordingly, the second matching unit 39 is effectively not connected to the transmission antenna 27. Thus, when the transmission circuit 26 transmits a wireless signal of the third frequency, the third matching unit 44 performs impedance matching between the transmission antenna 27 and the transmission circuit 26.

Since the first matching unit 35, the second matching unit 39, and the third matching unit 44 are prevented from affecting each other, impedance matching can be performed regardless of whether the frequency of the wireless signal is the first frequency, the second frequency, or the third frequency.

The matching circuit 31 may be connected to the reception antenna 51. The matching circuit 31 may be placed upstream or downstream of the reception antenna 51. The matching circuit 31 performs impedance matching between the reception antenna 51 and the reception circuit 52. The reception antenna 51 is an example of an antenna. The reception circuit 52 is an example of a wireless communication circuit.

The transmitter 20 may be attached to the tire 14.

As long as the matching circuit 31 is provided in a device that performs communication using wireless signals of multiple frequencies, the matching circuit 31 may be provided in a device different from the transmitter 20.

### REFERENCE SIGNS LIST

11) Vehicle; 13) Wheel; 20) Transmitter; 26) Transmission Circuit, which is Wireless Communication Circuit; 27) Transmission Antenna, which is Antenna; 31) Matching Circuit; 32) First Parallel Resonance Circuit; 33) First Capacitor; 34) First Coil; 35) First Matching Unit; 36) Second Parallel Resonance Circuit; 37) Second Capacitor; 38) Second Coil; 39) Second Matching Unit

1. An impedance matching circuit connected to an antenna, the impedance matching circuit comprising:
a first parallel resonance circuit including a first coil and a first capacitor that are connected in parallel with each other, the first parallel resonance circuit having a resonance frequency that is a first frequency;
a second parallel resonance circuit including a second coil and a second capacitor that are connected in parallel with each other, the second parallel resonance circuit having a resonance frequency that is a second frequency;
a first matching circuit configured to perform impedance matching between the antenna and a wireless communication circuit at the second frequency, the first matching circuit being connected in series with the first parallel resonance circuit; and
a second matching circuit configured to perform impedance matching between the antenna and the wireless communication circuit at the first frequency, the second matching circuit being connected in series with the second parallel resonance circuit,
wherein the first parallel resonance circuit and the second parallel resonance circuit are connected in parallel with each other and connected in series with the antenna.

2. A transmitter attached to a wheel of a vehicle, the transmitter comprising:
a transmission antenna;
a transmission circuit; and
an impedance matching circuit that performs impedance matching between the transmission antenna and the transmission circuit, wherein
the impedance matching circuit includes:
a first parallel resonance circuit including a first coil and a first capacitor that are connected in parallel with each other, the first parallel resonance circuit having a resonance frequency that is a first frequency;
a second parallel resonance circuit including a second coil and a second capacitor that are connected in parallel with each other, the second parallel resonance circuit having a resonance frequency that is a second frequency;
a first matching circuit configured to perform impedance matching between the transmission antenna and the transmission circuit at the second frequency, the first matching circuit being connected in series with the first parallel resonance circuit; and
a second matching circuit configured to perform impedance matching between the transmission antenna and the transmission circuit at the first frequency, the second matching circuit being connected in series with the second parallel resonance circuit, and
the first parallel resonance circuit and the second parallel resonance circuit are connected in parallel with each other and connected in series with the transmission antenna.

3. The transmitter according to claim 2, wherein the impedance matching circuit is placed upstream of the transmission antenna.

4. The transmitter according to claim 2, wherein the impedance matching circuit is placed between the transmission circuit and the transmission antenna.
